(19) United States
(12) Patent Application Publication
(10) Pub. No.: US 2008/0160427 A1
(43) Pub. Date: Jul. 3, 2008

(54) PHOTO MASK FOR DEPRESSING HAZE AND METHOD FOR FABRICATING THE SAME

(75) Inventor: Yong Dae Kim, Cheongju-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/770,531

(22) Filed: Jun. 28, 2007

(30) Foreign Application Priority Data
Dec. 29, 2006 (KR) 10-2006-138840

(51) Int. Cl. G03F 1/00

(52) U.S. Cl. 430/5

(57) ABSTRACT

A photo mask includes a transparent substrate, a light shielding layer pattern over the transparent substrate, and an ion-reaction preventing layer covering the transparent substrate and the light shielding layer pattern.

### CROSS-REFERENCE TO RELATED APPLICATIONS

The priority of Korean patent application number 10-2006-138840, filed on 29 Dec. 2006, the disclosure of which is incorporated by reference in its entirety, is claimed.

### BACKGROUND OF THE INVENTION

The invention relates to a photo mask and, more particularly, to a photo mask for depressing haze and a method for fabricating the photomask.

As semiconductor devices become more highly integrated, the sizes of patterns formed on a wafer continue to decrease. To form such fine patterns, a photolithography process using a photo mask is used. With the photolithography process, a photoresist layer is applied onto a material layer on which a desired pattern will be formed, and light is irradiated onto a part of the photoresist layer through a photo mask having a predetermined light shielding pattern. Subsequently, the irradiated part of the photoresist layer is removed by a developing process using a developer solution, so as to form a photoresist layer pattern. The photoresist layer pattern is used to expose a part of the material layer such that the exposed part of the material layer is removed by an etching process using the photoresist layer pattern as an etching mask. In this way, a material layer pattern, corresponding to the light shielding pattern of the photo mask, can be formed.

FIGS. 1 and 2 are sectional views illustrating examples of a conventional photo mask. As shown in FIG. 1, a binary photo mask 100 is configured such that a light shielding layer pattern 130 is disposed on a transparent substrate, illustratively a quartz plate 110. Also, as shown in FIG. 2, a phase shift photo mask 200 is configured such that a phase shift layer pattern 220 is disposed on a transparent substrate 210 and in turn, a light shielding layer pattern 230 is disposed on a partial surface of the phase shift layer pattern 220.

In the implementation of a photolithography process using the above described photo masks, if impurities exist on the photo mask, the impurities may be transcribed onto a photoresist layer, thus making it impossible to achieve a photoresist layer pattern having a desired profile. Consequently, there is a possibility that an unwanted pattern is formed on the material layer. In particular, with the tendency that the wavelength of a light source used in an exposure process is gradually shortened to enhance pattern resolution, the generation rate of haze as a growing defect increases. Specifically, residual ions, existing on a surface of the photo mask, do not cause an optical reaction when a light source having a long wavelength is used, but have a risk of causing an optical reaction when a short-wavelength light source is used. If the size of the residual ions increases beyond a critical value by the optical reaction, an increasingly large haze results.

The haze causes a defect in the transcription of a pattern. Therefore, it is necessary to remove the haze for example by a wet cleaning process (e.g., with sulfuric acid) capable of regulating the types, composition ratios, and temperatures of chemical materials, or a cleaning using de-ionized water, which is selected in consideration of the purpose of the process. However, in the case of a sulfuric acid cleaning process, there occurs a reaction product compound having a formula Cr₂(SO₄)₃ if a light shielding layer is a chromium (Cr) layer. Also, in the case of a cleaning process using an ammonia-containing cleaning solution, there occurs a reaction product compound having a formula of 6(NH₄)₇MoO₃ if a phase shift layer is a molybdenum silicon oxide nitride (MoSiON) layer. In conclusion, a cleaning process using a sulfuric acid peroxide mixture (SPM) cleaning solution and a cleaning process using an ammonia-containing standard clean (SC-1) cleaning solution may adversely result in a haze causing factor. Although a cleaning process not using sulfuric acid or ammonia is contemplated to solve the above problem, such alternative processes causes significant deterioration in the removal efficiency of a defect and do not comply with the essential purpose of a cleaning process.

### BRIEF SUMMARY OF THE INVENTION

In one embodiment, the invention provides a photo mask including: a transparent substrate; a light shielding layer pattern over the transparent substrate; and an ion-reaction preventing layer over an exposed surface of the transparent substrate and the light shielding layer pattern.

In another embodiment, the invention provides a photo mask including; a transparent substrate; a phase shift layer pattern over the transparent substrate; a light shielding layer pattern only over a partial surface of the phase shift layer pattern; and an ion-reaction preventing layer over an exposed surface of the transparent substrate, the phase shift layer pattern, and the light shielding layer pattern.

In a further embodiment, the invention provides a method for fabricating a photo mask including the steps of: forming a light shielding layer pattern over a transparent substrate; and, forming an ion-reaction preventing layer over the transparent substrate and the light shielding layer pattern.

In yet another embodiment, the invention provides a method for fabricating a photo mask including the steps of: forming a phase shift layer pattern on a transparent substrate; forming a light shielding layer pattern only over a partial surface of the phase shift layer pattern; and forming an ion-reaction preventing layer over the transparent substrate, the phase shift layer pattern, and the light shielding layer pattern.

### BRIEF DESCRIPTION OF THE DRAWINGS

FIG. 1 is a sectional view illustrating one example of a conventional photo mask.

FIG. 2 is a sectional view illustrating another example of a conventional photo mask.

FIG. 3 is a sectional view illustrating a photo mask according to an embodiment of the invention.

FIG. 4 is a sectional view illustrating a photo mask according to another embodiment of the invention.

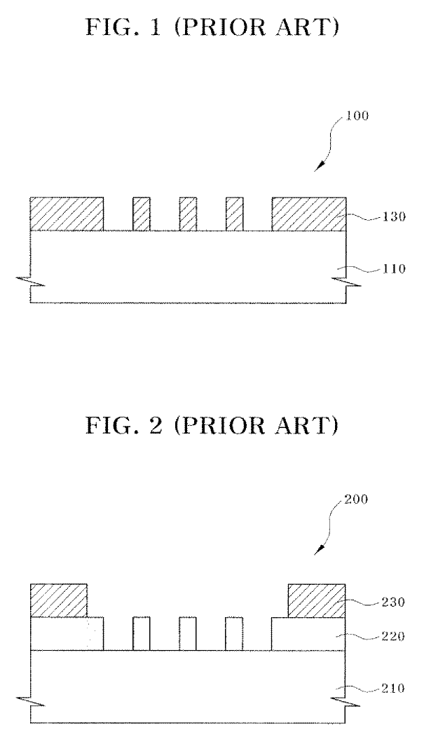

### DETAILED DESCRIPTION OF THE INVENTION

Exemplary embodiments of the invention are described in detail below, with reference to the accompanying drawings. However, the invention may be embodied in a variety of different forms, and the scope of the invention is not limited to the following description.

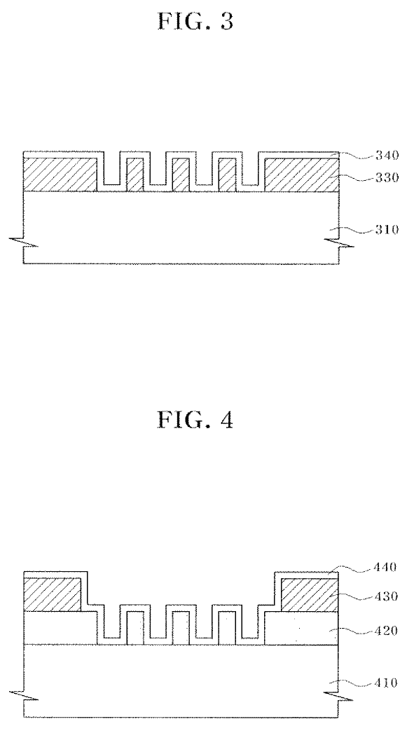

FIG. 3 is a sectional view illustrating a photo mask according to an embodiment of the invention. Referring to FIG. 3, the photo mask according to the present embodiment is configured as a binary photo mask. Specifically, a light shielding layer pattern 330 is disposed on a transparent quartz substrate 310. The light shielding layer pattern 330 is preferably formed of a chromium (Cr) layer, but other materials are also suitable, A region, in which the light shielding layer pattern 330 is disposed, forms a light shielding region preventing the transmission of light, and the remaining region, through which a surface of the transparent substrate 310 is exposed to the outside, forms a light transmission region. An ion-reaction preventing layer 340 is disposed on the exposed surface of the transparent substrate 310 and the light shielding layer pattern 330. As illustrated in FIG. 3, the ion-reaction preventing layer 340 completely covers the top surface of the photo mask structure.

The ion-reaction preventing layer 340 is preferably formed of a silicon oxide layer or silicon nitride layer. Since the ion-reaction preventing layer 340 is disposed even on the light transmission region, the ion-reaction preventing layer 340 must have minimal effect on the light transmissivity of the light transmission region. For this, the ion-reaction preventing layer 340 preferably has a thickness in a range of 3 Å to 90 Å. The ion-reaction preventing layer 340 restricts the outgassing of residual ions on the surface of the photo mask. In addition, the ion-reaction preventing layer 340 prevents a chemical reaction between certain ions in air and the residual ions on the surface of the photo mask. Moreover, even when a cleaning process using a sulfuric acid- or an ammonia-containing cleaning solution is performed, the ion-reaction preventing layer 340 can prevent sulfuric acid or ammonia from reacting with chromium (Cr) or other materials in the light shielding layer pattern 330. As a result, the residual ions on the surface of the photo mask can be easily removed, with a cleaning process using ultra-pure water, for example

To fabricate the above described photo mask, first, the light shielding layer pattern 330 is formed on the transparent substrate 310. Specifically, after a light shielding layer is formed on the transparent substrate 310, a resist layer pattern is formed on the light shielding layer to expose a part of the light shielding layer. The resist layer pattern may be formed by an electron beam lithography process, for example. Subsequently, the exposed part of the light shielding layer is removed by an etching process using the resist layer pattern as an etching mask. After removing the photoresist layer pattern, the ion reaction preventing layer 340 is preferably formed throughout the surface of the photo mask. The ion-reaction preventing layer 340 is formed of a silicon oxide layer or silicon nitride layer preferably by a chemical vapor deposition (CVD) method or by a sputtering method.

FIG. 4 is a sectional view illustrating a photo mask according to another embodiment of the invention. Referring to FIG. 4, the photo mask according to the illustrated embodiment is configured as a phase shift photo mask. Specifically, the phase shift layer pattern 420 is disposed on the transparent substrate 410. The phase shift layer pattern 420 is preferably formed of a molybdenum silicon oxide nitride (MoSiON) layer, but other materials may be suitable. The light shielding layer pattern 430 is disposed on a partial surface of the phase shift layer pattern 420. The light shielding layer pattern 430 is preferably formed of a chromium (Cr) layer, but other materials may be suitable. A region in which only the phase shift layer pattern 420 is disposed forms a phase shift region for shifting the phase of light, and a region in which the light shielding layer pattern 430 is disposed forms a light shielding region not allowing the transmission of light. Also, a region through which a surface of the transparent substrate 410 is exposed forms a light transmission region. The ion-reaction preventing layer 440 is disposed on the exposed surface of the transparent substrate 410, the phase shift layer pattern 420, and the light shielding layer pattern 430. As illustrated in FIG. 4, the ion-reaction preventing layer 340 completely covers the top surface of the photo mask structure.

The ion-reaction preventing layer 440 is preferably formed of a silicon oxide layer or silicon nitride layer. Since the ion-reaction preventing layer 440 is disposed even on the phase shift region and the light transmission region, the ion-reaction preventing layer 440 must have a minimal effect on the phase shifting performance of the phase shift region and the light transmissivity of the light transmission region. For this, the ion-reaction preventing layer 440 preferably has a thickness in a range of 3 Å to 90 Å. The ion-reaction preventing layer 440 restricts the outgassing of residual ions on the surface of the photo mask. In addition, the ion-reaction preventing layer 440 prevents a chemical reaction between certain ions in air and the residual ions on the surface of the photo mask. Moreover, even when a cleaning process using a sulfuric acid- or an ammonia-containing cleaning solution is performed, the ion-reaction preventing layer 440 can prevent sulfuric acid or ammonia from reacting with molybdenum silicon oxide nitride (MoSiON) or another material constituting the phase shift pattern 420 or chromium (Cr) or another material constituting the light shielding layer pattern 430. As a result, the residual ions on the surface of the photo mask can be easily removed with a cleaning process using ultra-pure water, for example.

To fabricate the above described photo mask, first, the phase shift layer pattern 420 is formed on the transparent substrate 410 and in turn, the light shielding layer pattern 430 is formed on the phase shift layer pattern 420. The forming method of the phase shift layer pattern 420 and the forming method of the light shielding layer pattern 430 are identical to the forming method of the light shielding layer pattern 330 with respect to the previously described embodiment. After forming the light shielding layer pattern 430, the ion-reaction preventing layer 440 is preferably formed throughout the surface of the photo mask. The ion reaction preventing layer 44015 preferably formed of a silicon oxide layer or silicon nitride layer, preferably by a chemical vapor deposition (CVD) method or sputtering method. In this case, if a processing temperature exceeds 250 degrees Celsius, the light transmissivity of molybdenum silicon oxide nitride (MoSiON) or another material constituting the phase shift layer pattern 420 may be changed. Accordingly, the processing temperature is preferably kept at a value less than 250 degrees Celsius.

As apparent from the foregoing description, with a photo mask and a method for fabricating the same according to the invention, an ion-reaction preventing layer is formed throughout a surface of the photo mask. This has an advantage of preventing an unwanted reaction of residual ions even upon an exposure process using a short-wavelength light source and a cleaning process using a sulfuric acid or an ammonia-containing cleaning solution.

What is claimed is:

1. A photo mask comprising:
a transparent substrate;
a light shielding layer pattern over the transparent substrate; and
an ion-reaction preventing layer over an exposed surface of the transparent substrate and the light shielding layer pattern.

2. The photo mask according to claim 1, wherein the ion-reaction preventing layer comprises a silicon oxide layer or a silicon nitride layer.

3. The photo mask according to claim 1, wherein the ion-reaction preventing layer has a thickness in a range of 3 Å to 90 Å.

4. The photo mask according to claim 1, wherein the ion-reaction preventing layer completely covers the exposed surface of the transparent substrate and the light shielding layer pattern.

5. A photo mask comprising:
a transparent substrate;
a phase shift layer pattern over the transparent substrate;
a light shielding layer pattern only over a partial surface of the phase shift layer pattern; and
an ion-reaction preventing layer over an exposed surface of the transparent substrate, the phase shift layer pattern, and the light shielding layer pattern.

6. The photo mask according to claim 5, wherein the ion reaction preventing layer comprises a silicon oxide layer or a silicon nitride layer.

7. The photo mask according to claim 5, wherein the ion-reaction preventing layer has a thickness in a range of 3 Å to 90 Å.

8. The photo mask according to claim 5, wherein the ion-reaction preventing layer completely covers the exposed surface of the transparent substrate, the phase shift layer pattern, and the light shielding layer pattern.

9. A method for fabricating a photo mask, comprising the steps of:
forming a light shielding layer pattern over a transparent substrate; and
forming an ion-reaction preventing layer over the transparent substrate and the light shielding layer pattern.

10. The method according to claim 9, wherein the ion-reaction preventing layer comprises a silicon oxide layer or a silicon nitride layer.

11. A method for fabricating a photo mask, comprising the steps of:
forming a phase shift layer pattern over a transparent substrate;
forming a light shielding layer pattern only over a partial surface of the phase shift layer pattern; and
forming an ion-reaction preventing layer over the transparent substrate, the phase shift layer pattern, and the light shielding layer pattern.

12. The method according to claim 11, wherein the ion-reaction preventing layer comprises a silicon oxide layer or a silicon nitride layer.

13. The method according no claim 11, wherein the ion-reaction preventing layer formed at a temperature that a light transmitting ratio of the phase shift layer pattern is unchanged.

14. The method according to claim 13, the temperature is not more than 250 degrees Celsius.
